(19) United States
(12) Patent Application Publication
(10) Pub. No.: US 2007/0054460 A1
(43) Pub. Date: Mar. 8, 2007

(54) SYSTEM AND METHOD FOR PROVIDING A NANOSCALE, HIGHLY SELECTIVE, AND THERMALLY RESILIENT SILICON, GERMANIUM, OR SILICON-GERMANIUM ETCH-STOP

(75) Inventor: Darwin G. Enicks, Colorado Springs, CO (US)

Correspondence Address: Schneck & Schneck, P.O. Box 2-E, San Jose, CA, 95109-0005, US

(73) Assignee: Atmel Corporation, San Jose, CA (US)

(21) Appl. No.: 11/554,430

(22) Filed: Oct. 30, 2006

Related U.S. Application Data
(63) Continuation-in-part of application No. 11/467,480, filed on Aug. 25, 2006.
(63) Continuation-in-part of application No. 11/166,287, filed on Jun. 23, 2005.

(51) Int. Cl. H01L 21/331

(52) U.S. Cl. 438/312

(57) ABSTRACT

A method and resulting etch-stop layer comprising a silicon-germanium layer and a dopant layer within the silicon-germanium layer. The silicon-germanium layer is comprised of less than about 70% germanium and contains one or more dopant elements selected from the group consisting of boron and carbon. The dopant layer has one or more of the dopant elements and an FWHM thickness value of less than 50 nanometers.

### CROSS-REFERENCE TO RELATED APPLICATION

This application is filed as a continuation-in-part of U.S. patent application Ser. No. 11/166,287 entitled “Method for Growth and Optimization of Heterojunction Bipolar Transistor Film Stacks by Remote Injection” filed Jun. 23, 2005 and Ser. No. 11/467,480 entitled “A Heterojunction Bipolar Transistor (HBT) with Periodic Multilayer Base” filed Aug. 25, 2006, both of which are hereby incorporated by reference in their entirety.

### TECHNICAL FIELD

The invention relates generally to methods of fabrication of integrated circuits (ICs). More particularly, the invention is a method of fabricating a highly selective carbon etch-stop in ICs in which the etch-stop has little diffusion into surrounding semiconductor layers even when subjected to elevated temperatures.

### BACKGROUND ART

Several material systems have emerged as key facilitators to extend Moore's law well into the next decade. These key facilitators include (1) silicon-on-insulator (SOI), (2) silicon-germanium (SiGe) and (3) strained silicon. With reference to SOI and related technologies, there are numerous advantages associated with an insulating substrate. These advantages include reduced parasitic capacitances, improved electrical isolation, and reduced short-channel-effects. Advantages of SOI can be combined with energy bandgap and carrier mobility improvements offered by Si₁₋ₓGeₓ and strained silicon devices.

SOI substrates generally include a thin layer of silicon on top of an insulator. Integrated circuit components are formed in and on the thin layer of silicon. The insulator can be comprised of insulators such as silicon dioxide (SiO₂), sapphire, or various other insulative materials.

Currently, several techniques are available to fabricate SOI substrates. One technique for fabricating SOI substrates is separation by implantation of oxygen (SIMOX). In a SIMOX process, oxygen is implanted below a surface of a silicon wafer. A subsequent anneal step produces a buried silicon dioxide layer with a silicon overlayer. However, the time required for an implantation in a SIMOX process can be extensive and, consequently, cost prohibitive. Moreover, an SOI substrate formed by SIMOX may be exposed to high surface damage and contamination.

Another technique is bond-and-etch-back SOI (BESOI) where an oxidized wafer is first diffusion-bonded to a non-oxidized wafer. With reference to FIG. 1A, a silicon device wafer 100 and a silicon handle wafer 150 comprise major components for forming a BESOI wafer. The silicon device wafer 100 includes a first silicon layer 101, which will servo as a device layer, an etch-stop layer 103, and a second silicon layer 105. The etch-stop layer 103 is frequently comprised of carbon. The silicon handle wafer 150 includes a lower silicon dioxide layer 107A, a silicon substrate layer 109, and an upper silicon dioxide layer 107B. The lower 107A and tipper 107B silicon dioxide layers are frequently thermally grown oxides formed concurrently.

In FIG. 1B, the silicon device wafer 100 and the silicon handle wafer 150 are brought into physical contact and bonded, one to the other. The initial bonding process is followed by a thermal anneal, thus strengthening the bond. The silicon device water 100 in the bonded pair is thinned. Initially, most of the second silicon layer 105 is removed by mechanical grinding and polishing until only a few tens of micrometers (i.e., “microns” or μm) remains. A high-selectivity wet or dry chemical etch removes remaining portions of the second silicon layer 105, stopping on the etch-strop layer 103. (Selectivity is discussed in detail, below.) An end-result of the second silicon layer 105 etch process is depicted in FIG. 1C.

During the etching process the silicon handle wafer 150 is protected by a coated mask layer (not shown). in FIG. 1D, the etch-stop layer 103 has been removed using another high-selectivity etchant. As a result of these processes, the first silicon layer 101, serving as a device layer, is transferred to the silicon handle wafer 150. A backside of the silicon substrate layer 109 is ground, polished and etched to achieve a desired overall thickness.

To ensure BESOI substrates are thin enough for subsequent fabrication steps as well as to meet contemporary demands for ever-decreasing physical size and weight constraints, BESOI requires the etch-stop layer 103 during the layer transfer process. Currently, two main layer transfer technologies exist: 1) splitting of a hydrogen-implanted layer from a device layer (a hydrogen implantation and separation process), and 2) selective chemical etching. Both technologies have demonstrated the ability to meet requirements of advanced semiconductor processing.

In the hydrogen implantation and separation process, hydrogen (H₂) is implanted into silicon having a thermally grown silicon dioxide layer. The implanted H₂ produces embrittlement of the silicon substrate underlying the silicon dioxide layer. The H₂ implanted water may be bonded with a second silicon water having a silicon dioxide overlayer. The bonded wafer may be cut across the wafer at a peak location of the hydrogen implant by appropriate annealing.

The BESOI process described is relatively free from ion implant damage inherent in the SIMOX process. However, the BESOI process requires a time consuming sequence of grinding, polishing, and chemical etching.

Contemporary Etch-stops

As described above, the BESOI process is a manufactulring-oriented technique to build silicon on insulator substrates and is partially dependent upon chemical etching.

Etch-stop performance is described by a mean etch selectivity, S, which defines an etch rate ratio of silicon to the etch-stop layer

$$S = \frac{{R}_{Si}}{{R}_{es}}$$

where R_{Si} is an etch rate of silicon and Rₑₛ is an etch rate of the etch-stop. Therefore, a selectivity value where S=1 relates to a case of no etch selectivity.

One method to evaluate etch-stop efficiency is to measure a maximum etch step height across an etch-stop and non-etch-stop boundary. In FIG. 2A, an etch-stop 203A is formed by ion implantation into a portion of a silicon substrate 201A. The etch-stop 203A has a thickness d₁ at time t=0 (i.e., prior to application of any etchant. At time t−t₁ (FIG. 2B), a partially etched silicon substrate 201B is etched to a depth h₁. The etch-stop 203A is now a partially etched etch-stop 203B. The partially etched etch-stop 203B is etched to a thickness of d₂. At time t=t₂ (FIG. 2C), the partially etched etch-stop 203B (see FIGS. 2A and 2B) has been completely etched and a fully etched silicon substrate 201C achieves a maximum etch step height of h₂. An etch rate of the etch-stop 203A (FIG. 2A) is partially dependent upon both a dopant material implanted as well as an implant profile of the dopant employed. From a practical point of view, the maximum etch step is a critical quantity since it determines an acceptable thickness variation of the device wafer after grinding and polishing prior to etch back in the BESOI process.

For example, if a: maximum etch step is 3 units, the allowable thickness non-uniformity of the device wafer after the usual mechanical thinning procedure should be less than 1.5 units The mean, etch selectivity, S, can be derived from the effective etch-stop layer thickness d₁ and the maximum etch step h₂ as

$$S = \frac{\frac{{d}_{1} + {h}_{2}}{t}}{\frac{{d}_{1}}{t}} \\ ⇓ \\ S = 1 + \frac{{h}_{2}}{{d}_{1}}$$

where t is the etch time required to reach the maximum etch step height h₂. In the prior example, t₂ is the etch time required to reach the maximum etch step height h₂.

In addition to problems created by reduced selectivity, other problems may arise with using carbon or boron as an etch-stop. A skilled artisan recognizes that carbon diffuses readily in pure silicon and thus the etch-stop layer readily increases in thickness. Boron also diffuses readily in silicon and grows in thickness after subsequent anneal steps. Carbon and boron etch-stop layers of the prior art are frequently hundreds of nanometers in width (at full-width half-maximum (FWHM)). Therefore, what is needed is an extremely thin and robust etch-stop layer having a high etchant selectivity in comparison with silicon.

### SUMMARY

In an exemplary embodiment, the present invention is an etch-stop layer comprising a silicon layer containing one or more dopant elements selected from the group consisting of germanium boron, and carbon. A dopant layer is contained within the silicon layer. The dopant layer is comprised of one or more of the dopant elements and has a full-width half-maximum (FWHM) thickness value of less than 50 nanometers.

In another exemplary embodiment, the present invention is an etch-stop layer comprising a silicon-germanium layer and a dopant layer within the silicon-germanium layer. The silicon-germanium layer is comprised of less than about 70% germanium and contains one or more dopant elements selected from the group consisting; of boron and carbon. The dopant layer has one or more of the dopant elements and an FWHM thickness value of less than 5 nanometers.

In another exemplary embodiment, the present invention is a method to fabricate an etch-stop. The method includes flowing a carrier gas over a substrate in a deposition chamber, flowing a silicon precursor gas over the substrate in the deposition chamber, flowing a germanium precursor gas over the substrate, forming a silicon-germanium layer such that the silicon-germanium layer contains less than about 70% germanium, flowing a dopant precursor gas over the substrate in the deposition chamber, the dopant precursor gas selected from the group consisting of boron and carbon and forming a dopant layer to act as at least a portion of the etch-stop, and annealing the substrate to a temperature of 900° C. or greater. A thickness of the dopant layer is maintained to less than 50 nanometers when measured as an FWHM value.

### BRIEF DESCRIPTION OF THE DRAWINGS

FIGS. 1A-1D are cross-sectional views of a prior art bond and etch back silicon on insulator (BESOI) fabrication technique.

FIGS. 2A-2C are cross-sectional views of an etch-stop formed on a silicon substrate, indicating a method to determine etch-stop efficiency.

FIG. 3 is a graph indicating relative etch rates for an ethylenediamine-pyrocatechol (EDP) wet-chemical etchant as a function of boron concentration contained within a silicon (100) substrate at different annealing temperatures.

FIG. 4 is a graph indicating etch selectivity for ethylenediamine-pyrocatechol (EDP) and 45% potassium hydroxide (KOH) wet-chemical etchants for a silicon (100) substrate compared with a carbon-implanted silicon layer as a function of carbon concentration.

FIG. 5 is a graph indicating a profile of carbon concentration as implanted or grown with a profile of the carbon after annealing.

FIG. 6 is a graph indicating a diffusion constant of boron as a function of germanium content at 800° C.

FIG. 7 is a graph indicating germanium diffusion at various anneal temperatures.

FIG. 8 is a graph indicating a full-width half-maximum (FWHM) depth of a boron profile produced in accordance with the present invention and measured after thermal annealing steps.

FIG. 9 is a graph indicating carbon diffusion depth in strained SiGe:C:B at various anneal temperatures.

FIG. 10 is a graph indicating boron diffusion depth in SiGe with carbon at various anneal temperatures.

FIGS. 11A-11D are concentration curves of dopants in a base substrate or semiconductor layer.

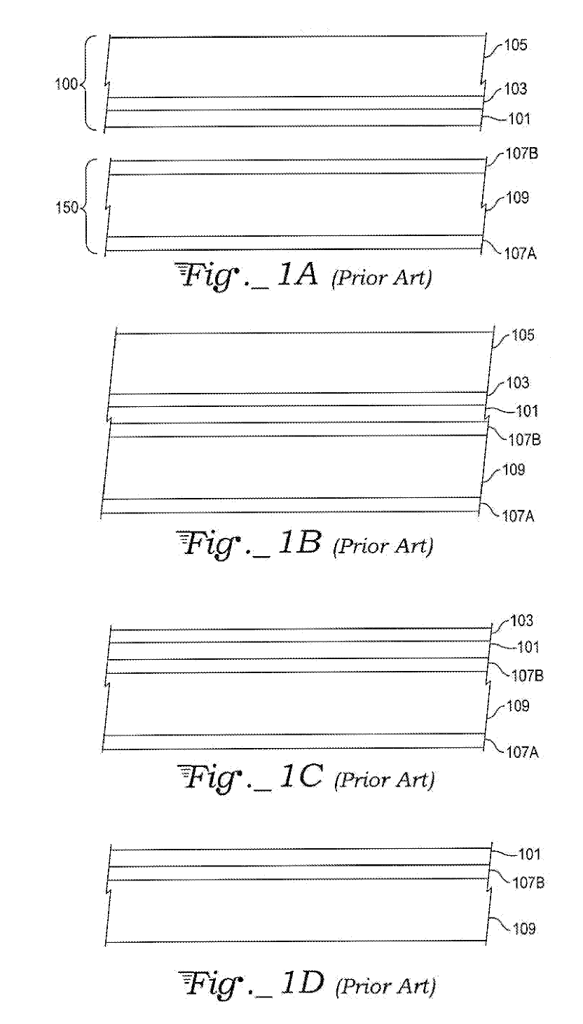

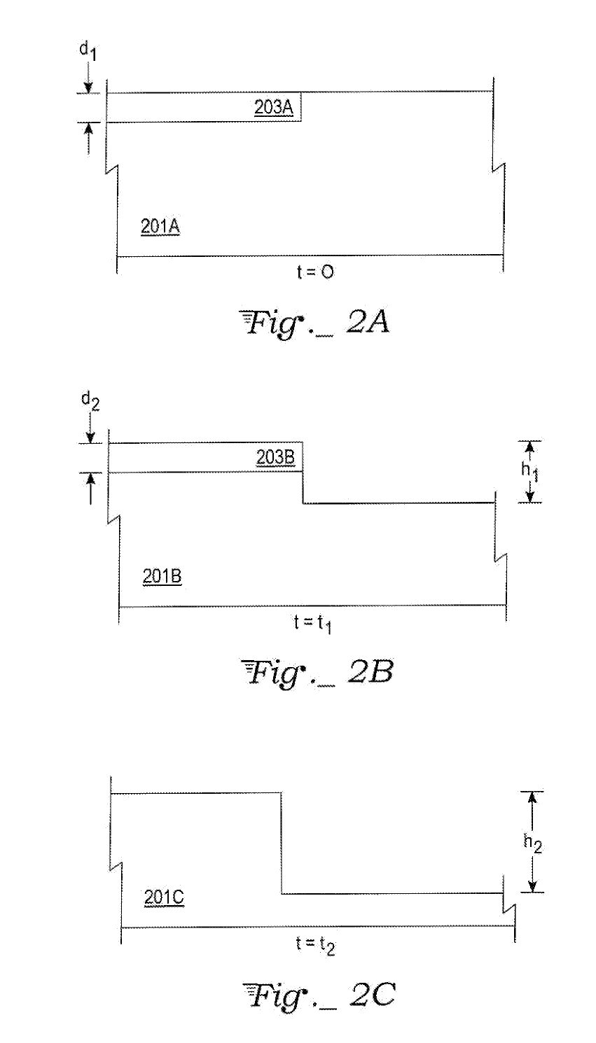

### DETAILED DESCRIPTION

Disclosed herein are a fabrication method and a structure resulting therefrom for a silicon (Si), germanium (Ge), and/or silicon-germanium (SiGe) nanoscale etch-stop. Various dopant types, such as boron (B), carbon (C), and germanium are considered for fabricating the nanoscale etch-stop. The nanoscale etch-stop described herein has particular applications in BESOI processing. However, the disclosed etch-stop is not limited only to BESOI applications.

A BESOI substrate fabricated in accordance with one exemplary embodiment of the present invention has particular applications in low-power and radiation-hardened CMOS devices. Incorporation of the present invention in various electronic devices simplifies certain fabrication processes, improves scalability of devices, improves sub-threshold slopes, and reduces parasitic capacitances.

Aqueous alkaline solutions are commonly used anisotropic silicon etchants. Two categories of aqueous alkaline solutions which may be employed are: (1) pure inorganic aqueous alkaline solutions such as potassium hydroxide (KOH), sodium hydroxide (NaOH), cesium hydroxide (CsOH), and ammonium hydroxide (NH₄OH); and (2) organic alkaline aqueous solutions such as ethylenediamine-pyrocatechol-water (aqueous EDP), tetramethyl ammonium hydroxide (TMAH or (CH₃)₄NOH) and hydrazine (H₄N₂). Other aqueous solutions may be employed in other embodiments.

Boron-Doped Silicon

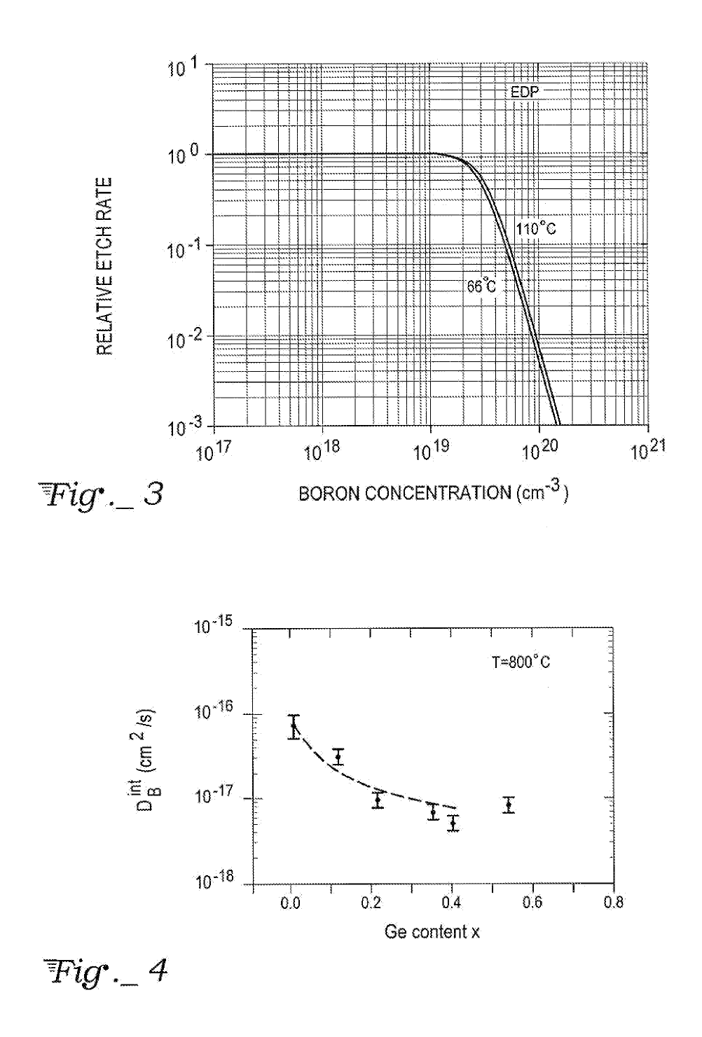

Silicon etch rates of all aqueous alkaline etchants are reduced significantly if silicon is doped with boron in concentrations exceeding 2×10¹⁹ cm⁻³. FIG. 3 graphically indicates a rapid falloff in relative etch rate as a function of boron concentration using EDP as an etchant. Notice that an effect of temperature (i.e., between temperatures of 110° C. and 66° C.) on relative etch rate is relatively small compared with the effect of boron concentration on etch rate.

At boron concentrations greater than 2.2×10¹⁹ cm⁻³ silicon becomes degenerated. The four electrons generated by an oxidation reaction have a high chance to recombine with holes which are available in large quantity in silicon. As a result the four electrons are no longer available for a subsequent reduction reaction which is required to continue the etching process. The only available thermal equilibrium electron concentration,

$$n = {n}_{i} / {p}^{2} ,$$

determines the remaining silicon etch rate. Since hole concentration p originating from heavily doped boron or any other Group III impurity is so high, the remaining number of the electrons is small. Thus, it is the hole concentration in silicon rather than the boron or any other elements of Group III concentration which determines etch rate. Experimental results show that approximately 8×10¹⁹ cm⁻³ and 1×10²⁰ cm⁻³ of boron doping are required to have a etch selectivity of 100 of lightly doped (100) silicon to the heavily boron-doped silicon in EDP and 10% KOH, respectively. At higher KOH concentrations the etch selectivity is lowered mainly due to the slower etch rate of lightly doped silicon in the KOH solutions. Conversely, an addition of isopropyl alcohol (IPA) into KOH solution can increase the etch selectivity due to its ability to adjust the relative water concentration in the etchant without significantly affecting the pH value.

As detailed above with reference to the prior art, boron (B) is traditionally provided via ion implantation. However, one problem with boron incorporation by ion implantation is that a resulting boron etch-stop layer is very wide following thermal treatments. The width of the boron layer is due to boron outdiffusion during any thermal treatments performed subsequent to the implant. One potential subsequent thermal treatment is a high temperature bonding step of the layer transfer process in BESOI processing. The boron outdiffusion is greatly enhanced by transient enhanced diffusion (TED) due to lattice damage and a large presence of silicon interstitial (S_{I}) atoms. The lattice damage and the large number of S_{I} atoms each contribute to anomalously high quantities of diffusion.

Widths of boron in ion implanted profiles can be greater than 200 nm to 300 nm depending on chosen quantities of ion implant energy and dosage. Typically, high dosage requirements also lead to a great deal of concentration-dependent outdiffusion. Therefore, the transferred silicon device layer thickness can exhibit a very wide thickness range since the etch process itself will have a wide profile range over which to stop on the boron-doped layer. The wide layer range poses significant process integration problems, especially when forming a deep (or even a shallow) trench isolation region.

Silicon interstitial pairing with boron results in a rate of diffusion that is generally much greater than occurs with boron alone. The intrinsic diffusion coefficient (D_{Si}) of silicon in silicon is approximately 560 whereas the intrinsic diffusion coefficient of boron (D_{B}) in silicon is approximately 1. Incorporating carbon (C) into boron-doped silicon minimizes a Si—B pair formation and thus reduces an overall rate of boron outdiffusion. In a heterojunction bipolar transistor (HBT), for example, the reduced boron outdiffusion results in less spreading of a p-type SiGe base region. Narrow base widths reduce transit times of minority carriers and improve a device shutoff frequency, fₜ. Adding carbon and/or germanium, the boron diffusion can be effectively mitigated at temperatures of approximately 1000° C. for 10 seconds or longer.

A device or substrate designer may prefer boron over carbon and/or Ge as a etch-stop depending on device requirements. For example, a design decision may be driven by a preferred majority carrier type and concentration, or a minority carrier type and concentration. One skilled in the art will recognize that adding carbon to a boron-doped layer will diminish carrier mobility. Consequently, more boron is required to compensate for the diminished carrier effect. A skilled artisan will further recognize that the addition of Ge to form a strained lattice in elemental or compound semiconductors enhances in-plane majority carrier hole mobility, but diminishes in-plane majority carrier electron mobility. Therefore, if boron is added to a carbon and/or germanium-doped lattice, the fabrication process must be completely characterized. The process will be a function of gas flows, temperatures, and pressures.

Further, intrinsic diffusivity of boron (D^{int}_{B}), measured in units of an area transfer rate (e.g., cm²/sec), in silicon can be substantial. However, the addition of Ge results in a significant reduction of intrinsic boron diffusivity. (Note: Intrinsic diffusivity of boron refers specifically to the diffusivity of a lone boron atom with no influence from diffusion “enhancing” species such as silicon interstitials as described above.) FIG. 4 indicates measured rates of intrinsic boron diffusivity at 800° C. as a function of Ge content, x, in Si₁₋ₓGeₓ.

Boron may be doped into either a silicon substrate or film, or a compound semiconductor substrate or film. The compound semiconductor film may be chosen from a Group III-V semiconductor compound such as SiGe, GaAs, or InGaAs. Alternatively, a Group II-VI semiconductor compound may be chosen such as ZnSe, CdSe, or CdTe.

Carbon-Doped Silicon

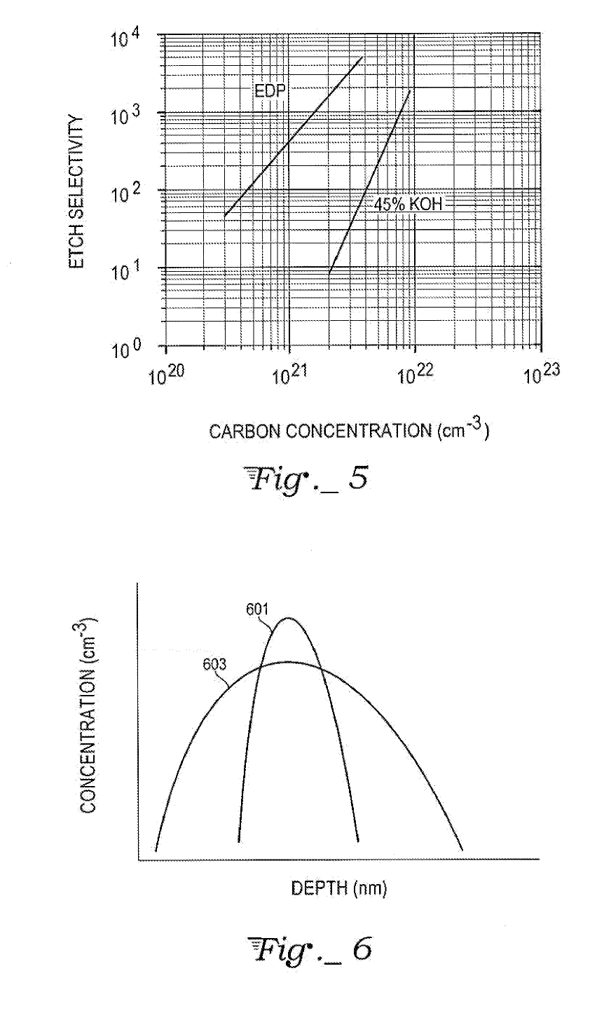

The graph of FIG. 5 indicates etch selectivity differences between non-aqueous EDP and a 45% KOH etchant for a silicon (100) substrate compared with a carbon-implanted silicon layer as a function of carbon concentration. Both etchants were used at 85° C. The graph of the EDP etch indicates a significantly reduced etch rate for carbon-doped silicon. At a carbon peak concentration of 1.5×10²¹ cm⁻³, the etch selectivity of EDP is approximately 1000. In the carbon concentrations shown, a continuous SiC layer is not formed. Rather, the etch-stop effect of the carbon-doped silicon layer appears to arise from chemical characteristics of a non-stoichiometric SiₓC₁₋ₓ alloy formed by randomly distributed implanted carbon atoms contained within the crystalline structure of host silicon atoms. SiC layers deposited by either CVD or implantation of carbon show almost no etch rate in either EDP, KOH, or any other alkaline solution.

Germanium-Doped Silicon

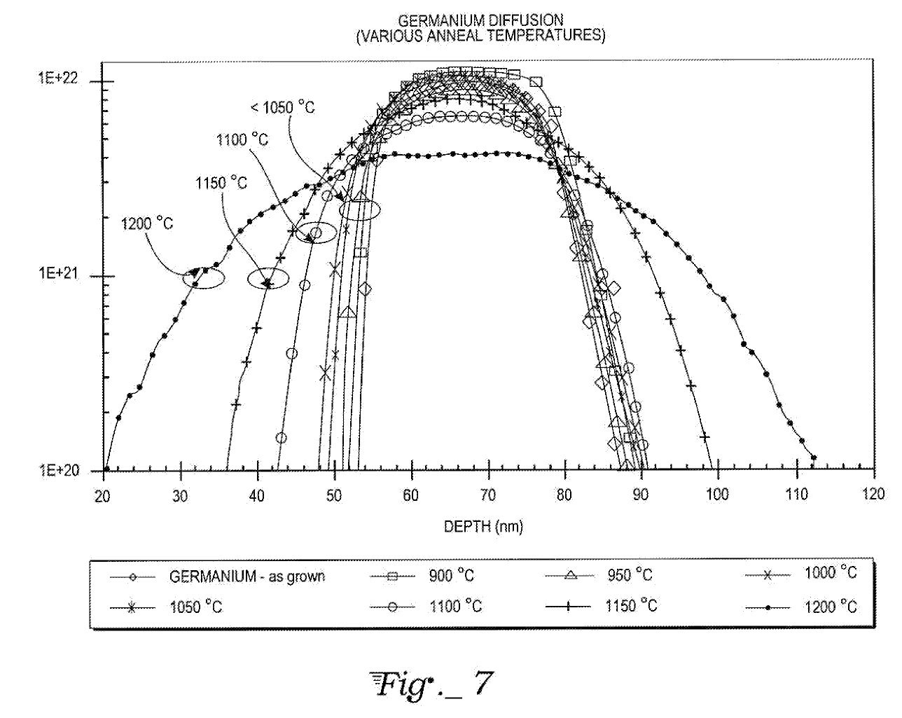

With reference to FIG. 6, a Si_{0.7}Ge_{0.3} layer, grown by molecular beam epitaxy (MBE) at 500° C. produced an etch selectivity of 17 with respect to silicon (100) prior to an 850° C. anneal. The germanium concentration in the layer was 1.5×10²² cm⁻³. An implanted (or grown) initial carbon profile 601 expands tremendously to a post-anneal profile 603. After the anneal, the selectivity dropped to a range from 10 to 12. The etch-stop effect is believed to be associated with strain induced by the relatively larger germanium atom.

However, with traditional germanium implantation and subsequent thermal anneals, a resulting germanium profile is frequently hundreds of nanometers in depth. This profile range is especially true when subsequent anneal temperatures are over 1000° C. An approximation of an “as-implanted” profile width, measured at FWHM, can be determined as

$$width ≅ \frac{dose}{peak concentration} \\ ⇓ \\ width ≅ \frac{5 ⨯ {10}^{15}}{3.1 ⨯ {10}^{20}} ≅ 161 nm$$

An Si_{1-x-y-z}GeₓC_{y}B_{z} Etch-Stop

Using a combined SiGe:C:B approach limits both carbon and boron diffusion in silicon when particular combinations of the elements are used. In an exemplary embodiment, composition ranges for the Si_{1-x-y-z}GeₓC_{y}B_{z} layers are:

x (Ge): 0% up to about 70% (3.5×10²² cm⁻³)

y (C): 0 cm⁻³ up to about 5×10²¹ cm⁻³

Z (B): 0 cm⁻³ up to about 5×10²¹ cm⁻³

Secondary-ion mass spectrometry (SIMS) data are displayed, in FIGS. 7-10, for boron, germanium, and carbon diffusion in silicon for various anneal temperatures (or bonding temperatures in the case of BESOI) from 900° C. to 1200° C. for 10 seconds. In particular, FIG. 7 indicates germanium diffusion in silicon at various temperatures. Even at a 1200° C. anneal temperature, a FWHM value of germanium diffusion of approximately 70 nm (i.e., a range of about 30 nm to 100 nm) is achieved. At temperatures of less than 1050° C., a FWHM value of germanium diffusion of less than 40 nm is indicated.

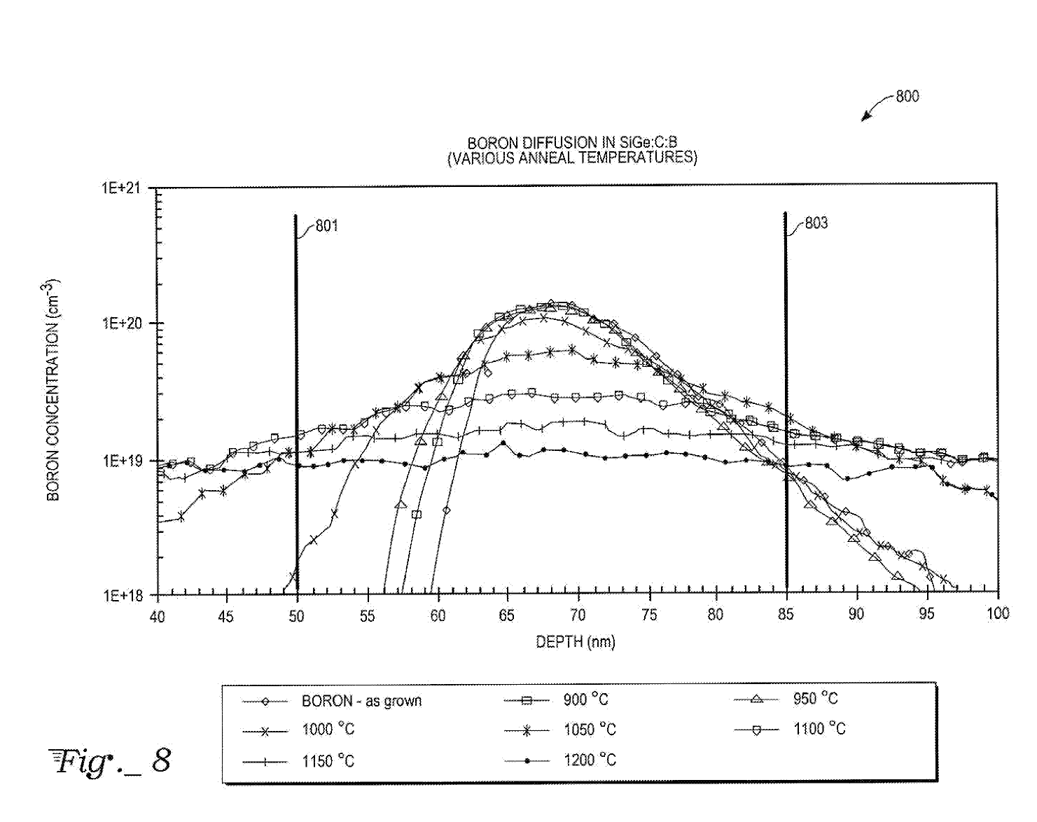

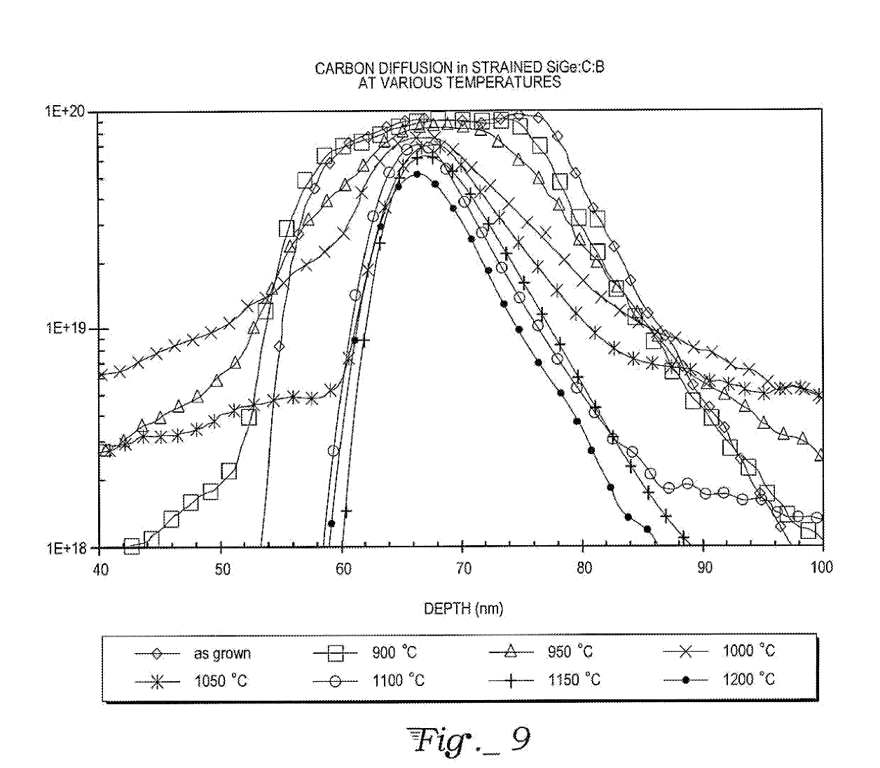

With reference to FIG. 8, a SIMS profile graph 800 represents data from a diffusion profile of boron in carbon and Ge-doped silicon (SiGe:C:B). A location of the Ge dopant is illustrated by a lower 801 and an upper 803 vertical line positioned at 50 nm and 85 nm depths, respectively. The boron remains relatively fixed up to temperatures of 1000° C., then diffuses rapidly at higher temperatures (anneal times are 10 seconds at each temperature). However, the presence of both carbon and Ge, as introduced under embodiments of the present invention, reduces boron outdiffusion. Depending on concentrations and temperatures involved, the presence of carbon and Ge reduces overall boron diffusion by a factor of ten or more. In a specific exemplary embodiment, the particular alloy of SiGe:C:B is Si_{0.975}Ge_{0.02}C_{0.002}B_{0.003}. Thus, a ratio of Si to Ge is approximately 50:1 and a ratio of B to C is approximately 1.5:1.

FIG. 9 indicates, in another embodiment, a significantly lower ratio Si to Ge SIMS profile. Carbon diffusion levels in strained SiGe:C:B are indicated as grown and at subsequent anneal temperatures of 900° C. to 1200° C. The data show carbon diffusion primarily from undoped spacer regions (not shown) in which the spacer regions have no B doping. However, a center region of the SIMS profile (i.e., at a depth of roughly 60 nm to 80 nm) indicates that carbon diffusion is significantly mitigated due to the presence of B in the SiGe film. In this exemplary embodiment, the SiGe:C:B film is 79.5% Si, 20% Ge, 0.2% C, and 0.3% boron, prior to thermal anneal (Si_{0.795}Ge_{0.2}C_{0.002}B_{0.003}) Thus a ratio of Si to Ge is approximately 4.1 and a ratio of B to C is approximately 1.5.1.

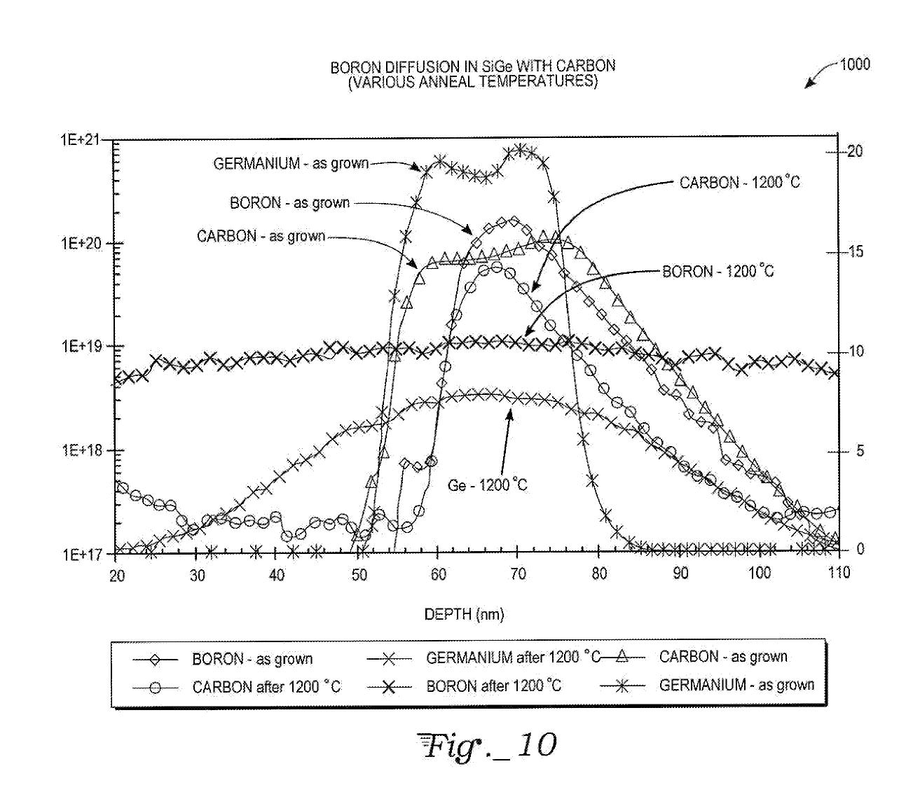

FIG. 10 is a SIMS profile 700 indicating boron diffusion depth in SiGe with carbon at various anneal temperatures. The SiGe film employed in this embodiment is also Si_{0.795}Ge_{0.2}C_{0.002}B_{0.003}, similar to the film used in producing the graph of FIG. 9. Note the SIMS profile 700 indicates that, following a 1200° C. anneal for 10 seconds, germanium has diffused from a peak of 20% (i.e., approximately 1.0×10²² atoms/cm³) to a peak concentration of 7.7% (i.e., approximately 3.85×10²¹ atoms/cm³). Boron has diffused from a peak of 1.5×10²⁰ atoms/cm³ to a peak of 1.0×10¹⁹ atoms/cm³. Additionally, carbon has diffused but the diffusion mechanism involved is due primarily to the SiGe spacers (the outside edges that contained only Ge and C during the initial growth). The carbon peak has diffused from 1.0×10²⁰ atoms/cm³ down to 7.0×10¹⁹ atoms/cm³ (indicating roughly a 30% peak reduction). The final diffused profile of the carbon is narrower than the as-grown profile. As a result, the final diffused carbon profile, even after a 1200° C. anneal is less than 20 nm wide at FWHM.

Fabrication Process for the Etch-stop Layer

Overall, process conditions can vary widely depending upon particular devices fabricated, specific equipment types employed, and various combinations of starting materials. However, in a specific exemplary embodiment, the process conditions generally entail the following process conditions, generally at pressures from less than 1 Torr to about 100 Torr and temperatures from 450° C. to 950° C.

| Precursor | | |
|---|---|---|
| Gas or | | |
| Carrier Gas | Flow Rate | Notes |
| GeH₄ | 0 sccm to 500 sccm | 0 sccm for Si, not Ge |
| SiH₄ | 5 sccm to 500 sccm | 0 sccm for Ge, not Si |
| B₂H₆ | 0 sccm to 500 sccm | 0 sccm = no B in Si or |
| | | SiGe |
| CH₃SiH₃ | 0 sccm to 500 sccm | 0 sccm = no C in Si or |
| | | SiGe |
| He | 0 sccm to 500 sccm | Optional - used for |
| | | low temperature growth |
| | | (e.g., <500° C.) |
| H₂ | 1 slpm to 50 slpm | |

In addition to germanium tetrahydride (GeH₄), another germanium precursor gas may be employed. Additionally, disilane (Si₂H₆) or another silicon precursor gas may be used in place of silane (SiH₄). Disilane deposits silicon at a faster rate and lower temperature than silane.

Additionally, boron trichloride (BCl₃) or any other boron precursor gas may be used in place of diborane (B₂H₆). A carbon precursor gas other than methyl silane (CH₃SiH₃) may be employed as the carbon precursor. Inert gases such as nitrogen (N₂), argon (Ar), helium (He), xenon (Xe), and fluorine (F₂) are all suitable carrier gases to substitute for H₂ as well.

All gas flow rates may be process, equipment, and/or device dependent. Therefore, gas flow rates outside of the exemplary ranges given may be fully acceptable.

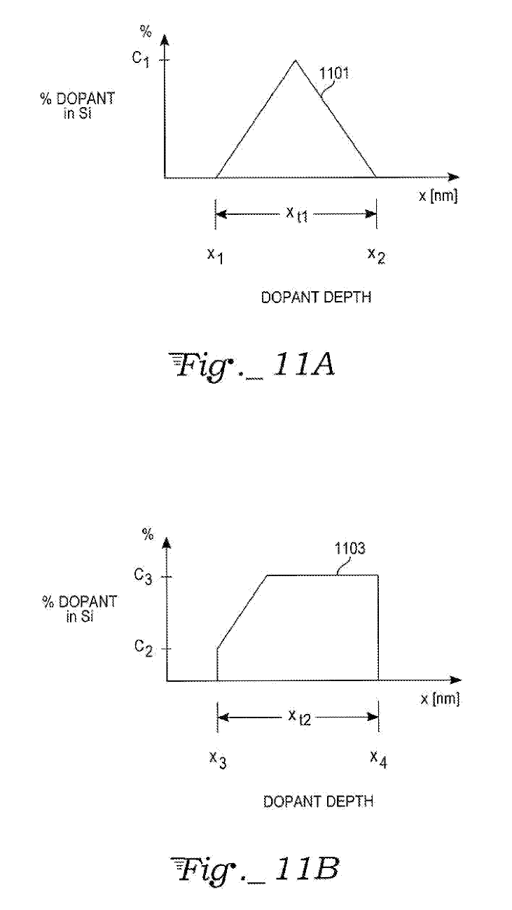

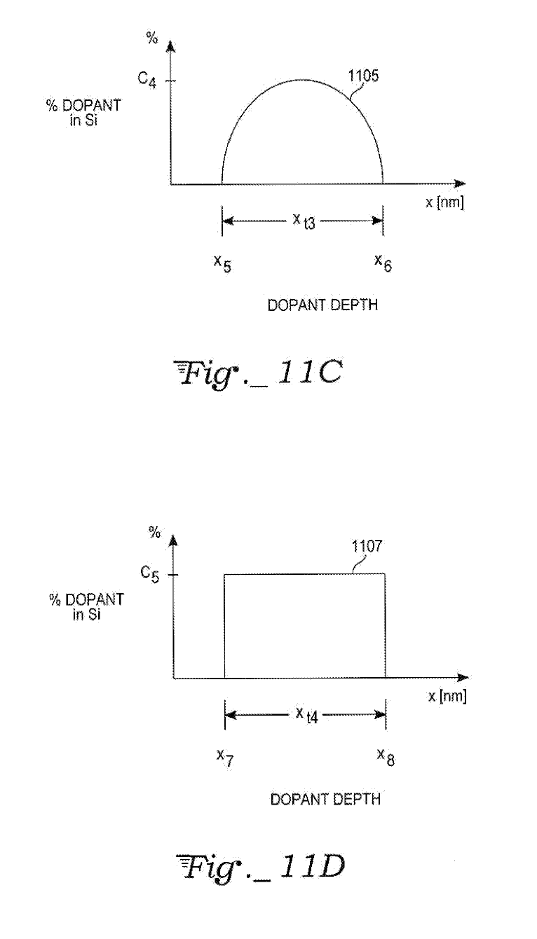

The Si_{1-x-y-z}GeₓC_{y}B_{z} layer may be deposited in various profiles as well depending upon electrical characteristics desired. With reference to FIG. 11A, a triangular dopant concentration profile 1101 of an electronic device employing the Si_{1-x-y-z}GeₓC_{y}B_{z} layer in a particular embodiment indicates an exemplary maximum dopant-layer depth, Xₜ₁, of between, for example, 1 nm and 50 nm. The concentration of dopant in the approximate center of the dopant layer where the dopant reaches its maximum value, C₁, is between 0.1 and 100%.

An electronic device with a trapezoidal dopant concentration profile 1103 of FIG. 11E has an exemplary dopant-layer depth, xₜ₂, of between approximately 1 nm and 50 nm. In this example, the concentration of dopant increases linearly from about 5% at level C₂ to about 100% at C₃.

A semicircular concentration profile 1105 of FIG. 11C has an exemplary dopant-layer depth, xₜ₃, of between approximately 1 nm, and 50 nm. The concentration of dopant increases in a semicircular, ellipsoidal, or parabolic manner to a maximum concentration as high as 100% at C₄.

A square or box type profile 1107 of FIG. 11D has an exemplary dopant-layer depth, xₜ₄, of between approximately 1 nm and 50 nm. The concentration of dopant increases in a square or rectangular manner to a maximum concentration as high as 100% at C₅.

The profiles 1101-1107 of FIGS. 11A-11D and their associated depths and concentration levels are merely exemplary and will vary depending upon, for example, a particular device type being fabricated. Formation of ramped profiles require ramping mass flow controllers from a lower/higher value to a higher/lower value. Either linear or non-linear techniques can be achieved with ramping methodologies. One skilled in the art will recognize that other shapes, depths, and concentrations are possible as well.

Amorphization-Enhanced Etch-Stop

As noted in FIG. 7, an implanted Ge profile is more resilient to outdiffusion than a CVD Ge profile. Therefore, additional process steps may be added. For example, following the CVD deposition of a SiGe:C:B nano-scale filmstack, an amorphization implant may be performed. The implant results in a reduction in film strain along a Si/SiGe heterojunction (contrary to contemporary literature findings). Therefore, be amorphizing the pseudomorphic SiGe:C:B layer the selectivity will be further enhanced. Species which have been found to be acceptable for this step include, among others, boron, germanium, silicon, argon, nitrogen, oxygen (monotonic), carbon, and Group III-V and Group II-VI semiconductors.

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, although process steps and techniques are shown and described in detail, a skilled artisan will recognize that other techniques and methods may be utilized which are still included within a scope of the appended claims. For example, there are frequently several techniques used for depositing a film layer (e.g., chemical vapor deposition, plasma-enhanced vapor deposition, epitaxy, atomic layer depositions, etc.). Although not all techniques are amenable to all film types described herein, one skilled in the art will recognize that multiple methods for depositing a given layer and/or film type may be used.

Additionally, many industries allied with the semiconductor industry could make use of the remote carbon injection technique. For example, a thin-film head (TFH) process in the data storage industry or an active matrix liquid crystal display (AMLCD) in the flat panel display industry could readily make use of the processes and techniques described herein. The term “semiconductor” should be recognized as including the aforementioned and related industries. The specification and drawings are, accordingly, to be regarded in an illustrative rather than a restrictive sense.

What is claimed is:

1. An etch-stop layer comprising:
a silicon layer containing one or more dopant elements selected from the group consisting of germanium, boron, and carbon;
a dopant layer within the silicon layer, the dopant layer having one or more of the dopant elements and having a full-width half-maximum (FWHM) thickness value of less than 50 nanometers.

2. The etch-stop layer of claim 1 wherein the silicon layer contains less than about 70% germanium.

3. The etch-stop layer of claim 1 wherein the silicon layer contains less than about 5×10²¹ atoms per cubic centimeter of boron.

4. The etch-stop layer of claim 1 wherein the silicon layer contains less than about 5×10²¹ atoms per cubic centimeter of carbon.

5. The etch-stop layer of claim 1 wherein the silicon layer is contained within a silicon substrate.

6. The etch-stop layer of claim 1 wherein the silicon layer is a silicon film layer.

7. The etch-stop layer of claim 1 wherein the one or more dopant elements has a triangular profile.

8. The etch-stop layer of claim 1 wherein the one or more dopant elements has a trapezoidal profile.

9. The etch-stop layer of claim 1 wherein the one or more dopant elements has a ellipsoidal profile.

10. The etch-stop layer of claim 1 wherein the one or more dopant elements has a semicircular profile.

11. The etch-stop layer of claim 1 wherein the one or more dopant elements has a parabolic profile.

12. The etch-stop layer of claim 1 wherein the one or more dopant elements has a box-shaped profile.

13. The etch-stop layer of claim 1 wherein the dopant layer is less than 20 nanometers measured as an FWHM value.

14. The etch-stop layer of claim 1 further comprising an amorphization implant, the amorphization implant being selected from the group consisting of boron, germanium, silicon, argon, nitrogen, oxygen, and carbon.

15. The etch-stop layer of claim 1 further comprising adding an amorphization implant, the amorphization implant being selected from the group consisting of Group III and Group V semiconductors.

16. The etch-stop layer of claim 1 further comprising an amorphization implant, the amorphization implant being selected from the group consisting of Group II and Group VI semiconductors.

17. An etch-stop layer comprising:
a silicon-germanium layer, the silicon-germanium layer comprised of less than about 70% germanium and containing one or more dopant elements selected from the group consisting of boron and carbon;
a dopant layer within the silicon germanium layer, the dopant layer having one: or more of the dopant elements and having a full-width half-maximum (FWHM) thickness value of less than 50 nanometers.

18. The etch-stop layer of claim 17 wherein the silicon-germanium layer contains less than about 5×10²¹ atoms per cubic centimeter of boron.

19. The etch-stop layer of claim 17 wherein the silicon-germanium layer contains less than about 5×10²¹ atoms per cubic centimeter of carbon.

20. The etch-stop layer of claim 17 wherein the silicon-germanium layer is contained within a silicon-germanium substrate.

21. The etch-stop layer of claim 17 wherein the silicon-germanium layer is a silicon-germanium film layer.

22. The etch-stop layer of claim 17 wherein the dopant layer is less than 20 nanometers measured as an FWHM value.

23. The etch-stop layer of claim 17 further comprising an amorphization implant, the amorphization implant being selected from the group consisting of boron, germanium, silicon, argon, nitrogen, oxygen, and carbon.

24. The etch-stop layer of claim 17 further comprising adding an amorphization implant, the amorphization implant being selected from the group consisting of Group III and Group V semiconductors.

25. The etch-stop layer of claim 17 further comprising an amorphization implant, the amorphization implant being selected from the group consisting of Group II and Group VI semiconductors.

26. A method to fabricate an etch-stop, the method comprising:
flowing a carrier gas over a substrate in a deposition chamber;
flowing a silicon precursor gas over the substrate in the deposition chamber;
flowing a germanium precursor gas over the substrate;
forming a silicon-germanium layer such that the silicon-germanium layer contains less than about 70% germanium;
flowing a dopant precursor gas over the substrate in the deposition chamber, the dopant precursor gas selected from the group consisting of boron and carbon and forming a dopant layer to act as at least a portion of the etch-stop;
annealing the substrate to a temperature of 900° C. or greater; and
maintaining a thickness of the dopant layer to less than 50 nanometers when measured as a full-width half-maximum (FWHM) value.

27. The method of claim 26 wherein the dopant layer is maintained at a thickness of less than about 20 nanometers in thickness when measured as an FWHM value

28. The method of claim 26 further comprising forming the at least a portion of the dopant layer to have a triangular profile.

29. The method of claim 26 further comprising forming the at least a portion of the dopant layer to have a trapezoidal profile.

30. The method of claim 26 further comprising forming the at least a portion of the dopant layer to have a semicircular profile.

31. The method of claim 26 further comprising forming the at least a portion of the dopant layer to have a ellipsoidal profile.

32. The method of claim 26 further comprising forming the at least a portion of the dopant layer to have a parabolic profile.

33. Thee method of claim 26 further comprising forming the at least a portion of the dopant layer to have a box-shaped profile.

34. The method of claim 26 further comprising adding an amorphization implant, the amorphization implant being selected from the group consisting of boron, germanium, silicon, argon, nitrogen, oxygen and carbon.

35. The method of claim 26 further comprising adding an amorphization implant, the amorphization implant being selected from the group consisting of Group III and Group V semiconductors.

36. The method of claim 26 further comprising adding an amorphization implant, the amorphization implant being selected from the group consisting of Group II and Group VI semiconductors.
